(19) United States
(12) Patent Application Publication
(10) Pub. No.: US 2012/0074094 A1
(43) Pub. Date: Mar. 29, 2012

(54) Manufacturing Method for Forming Circuit Structure on Non-Conductive Carrier

(75) Inventors: Cheng-Feng Chiang, Guishan Township (TW); Jung-Chuan Chiang, Guishan Township (TW); Wei-Cheng Fu, Yingge Township (TW)

(73) Assignee: KUANG HONG PRECISION CO., LTD., Guishan Township (TW)

(21) Appl. No.: 13/206,047

(22) Filed: Aug. 9, 2011

Related U.S. Application Data
(60) Provisional application No. 61/385,984, filed on Sep. 24, 2010.
(60) Provisional application No. 61/423,084, filed on Dec. 14, 2010.

(51) Int. Cl. H05K 3/10; H05K 3/22; B82Y 99/00

(52) U.S. Cl. 216/18; 427/98.5; 427/97.3; 977/742

(57) ABSTRACT

A manufacturing method of forming an electrical circuit on a non-conductive carrier comprises following steps. After providing an electrically non-conductive carrier, catalysts are dispersed on or in the electrically non-conductive carrier. A predetermined track structure is formed on the electrically non-conductive carrier to expose the catalysts on the surface of the predetermined track structure. The surface of the predetermined track structure containing the catalysts is metalized to form a conductor track.

This application claims priority to co-pending provisional application 61/423084, filed Dec. 14, 2010, and also claims priority to co-pending provisional application 61/385,984, filed Sep. 24, 2010.

### BACKGROUND OF THE INVENTION

1. Field of the Invention

The present invention relates to a manufacturing method, and more particularly to a manufacturing method for forming circuit structure on a non-conductive carrier.

2. Description of the Related Art

Since people trends to purchase 3C products with convenience and portability, these electronic products are developed toward the tendency of small, light weight and multifunction. The circuit design and manufacturing is also developed with light weight, small size and thin thickness.

Well known manners of manufacturing circuits usually include electroplating and chemical plating. By comparing with electroplating, chemical plating is also called electroless plating or autocatalytic plating and is that metal ions within aqueous solution are chemically reduced under a controlled environment without electroplating over the substrate. The advantages of chemical plating include uniform plating, few pore rate of plating layer, and multi-element alloy. Therefore, in the electronic products requiring higher uniform degree of metal layer thickness, for example, a manner of forming circuits of circuit components, such as a cell phone and a laptop computer, usually adopts chemical plating to manufacture the circuit components.

In a process of manufacturing a moduled interconnect device, a conventional technique is to disperse a metal oxide in a non-conductive carrier and provide a base through injection molding. Subsequently, any surface of the base is irradiated by laser to form a predetermined circuit pattern. While performing laser ablation on the surface of the base, the metal oxide on the surface is simultaneously exposed and activated to release metal nuclei. In the manufacturing process, to uniformly disperse the metal oxide in the non-conductive carrier, the metal oxide with a certain ratio must be provided. However, the metal nuclei released by the metal oxide are merely provided for reduction reaction of metallization of the surface of the predetermined circuit pattern. Cost consumption caused by laser activated metal oxide may not occur, and the possibility of recycling and reutilizing it may not occur as well.

In other conventional techniques, since a portion of catalyst is exposed on the surface of a non-predetermined track, metal may also be plated over the surface of the non-predetermined track during the subsequent metallization, resulting in increasing the defective fraction.

Moreover, in U.S. Pat. No. 7,060,421, titled “method of manufacturing conductor track structure”, because applied laser power must achieve the energy as well as the metal oxide releasing the metal nuclei, the service life of the laser source is reduced. U.S. Pat. Nos. 5,945,213 and 5,076,841 may form micro-wires with three-dimensional masks on a three-dimensional curved surface, resulting in higher costs.

### SUMMARY OF THE INVENTION

In view of the shortcomings of the prior art, the inventor(s) of the present invention based on years of experience in the related industry to conduct extensive researches and experiments, and finally developed a manufacturing method for forming circuit structure on a non-conductive carrier as a principle objective to achieve efficacies of simplifying a manufacturing process and reducing costs and defective fraction and to have an advantage of flexible implementation.

To achieve the foregoing objective, a manufacturing method for forming circuit structure on a non-conductive carrier is provided and comprises the following steps: providing a non-conductive carrier; dispersing a catalyst on the non-conductive carrier or in the non-conductive carrier; forming a predetermined track structure on the non-conductive carrier and exposing the catalyst on a surface of the predetermined track structure; and metalizing the predetermined track structure to form a conductive track.

A sandblasting, a laser irradiating or a chemical etching is utilized so that the predetermined track structure is formed on the non-conductive carrier to expose the catalyst on the predetermined track structure. The foregoing chemical etching does not only expose the catalyst, but also has some wetting effect to allow a face to be plated to have few hydrophilic features, thereby facilitating the proceeding of the subsequent chemical plating.

In the manufacturing method for forming circuit structure on a non-conductive carrier, a step of disposing an insulation layer on a non-conductive carrier containing the catalyst is further provided to form a composite body. Therefore, while subsequently performing the metallization, disposing the insulation layer can prevent the metal from plating on a surface of a non-predetermined track, thereby reducing the defective fraction.

The step of dispersing the catalyst over the non-conductive carrier is achieved by disposing a thin film containing the catalyst on the surface of the non-conductive carrier. The thin film can be ink, a plastic film, paint or organic polymer. Alternatively, the residual thin film can be selectively removed after forming the conductor track.

The non-conductive carrier can further include a heat conduction material, a heat column or a combination thereof to further increase the heat conduction efficiency. The heat conduction material can include a non-metal heat conduction material or a heat conduction material. The non-metal heat conduction material can be selected from a group consisting of graphite, graphene, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride and silicon carbide. The metal heat conduction material can be selected from a group consisting of lead, aluminum, gold, copper, tungsten, magnesium, molybdenum, zinc and silver. A material of the heat column can be selected from a group consisting of lead, aluminum, gold, copper, tungsten, magnesium, molybdenum, zinc, silver, graphite, grapheme, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride and silicon carbide.

The manufacturing method for forming circuit structure on a non-conductive carrier according to the invention has one or above two following advantages:
(1) In the manufacturing method of the invention, while using laser to expose the catalyst, the exposing sequence is performed with low power. The metal nuclei is settled for 10 to 15 minutes in the chemical plating process, and the catalyst is settled for 3 to 5 minutes in the chemical plating process so that the oxidation reduction reaction rate in the chemical plating process of the catalyst of the non-conductive carrier according to the invention is faster than the metal nuclei released by the metal oxidate that is activated by laser.
(2) In the manufacturing method of the invention, the residual thin film can be selected removed so that the catalyst within the thin film can be recycled and reutilized to further reduce the cost of circuit fabrication.
(3) In the manufacturing method for forming circuit structure on a non-conductive carrier according to the invention, the thin film containing the catalyst is disposed with an insulation layer so that while performing the metallization, undesirable influence caused by a portion of the catalyst that is exposed on the surface of the thin film can be avoided.
(4) In the manufacturing method for forming circuit structure on a non-conductive carrier according to the invention, since the non-conductive carrier can include the heat conduction material, the heat column or the combination thereof, the obtained circuit board can have excellent heat conduction and heat radiation efficiencies.

### BRIEF DESCRIPTION OF THE DRAWINGS

FIG. 1 is a flowchart of a manufacturing method for forming circuit structure on a non-conductive carrier in accordance with a first embodiment of the invention;

FIG. 2 is a cross-sectional drawing of a circuit in accordance with an embodiment of the invention;

FIG. 3 is a cross-sectional drawing of a circuit in accordance with the invention, wherein its predetermined track structure is formed on a thin film;

FIG. 4 is a cross-sectional drawing of a circuit in accordance with the invention, wherein its predetermined track structure is formed on a non-conductive carrier;

FIG. 5 is a flowchart of a manufacturing method for forming circuit structure on a non-conductive carrier in accordance with a second embodiment of the invention;

FIG. 6 is a cross-sectional drawing of a circuit obtained by the manufacturing method in accordance with the second embodiment of the invention, wherein its predetermined track structure is formed on a thin film;

FIG. 7 is a cross-sectional drawing of a circuit obtained by the manufacturing method in accordance with the second embodiment of the invention, wherein its predetermined track structure is formed on a non-conductive carrier;

FIG. 8 is a flowchart of a manufacturing method for forming circuit structure on a non-conductive carrier in accordance with a third embodiment of the invention;

FIG. 9 is a flowchart of a manufacturing method for forming circuit structure on a non-conductive carrier in accordance with a fourth embodiment of the invention; and

FIG. 10 is a cross-sectional drawing of a circuit containing a heat conduction material of the invention.

### DETAILED DESCRIPTION OF THE PREFERRED EMBODIMENTS

The foregoing and other technical characteristics of the present invention will become apparent with the detailed description of the preferred embodiments and the illustration of the related drawings.

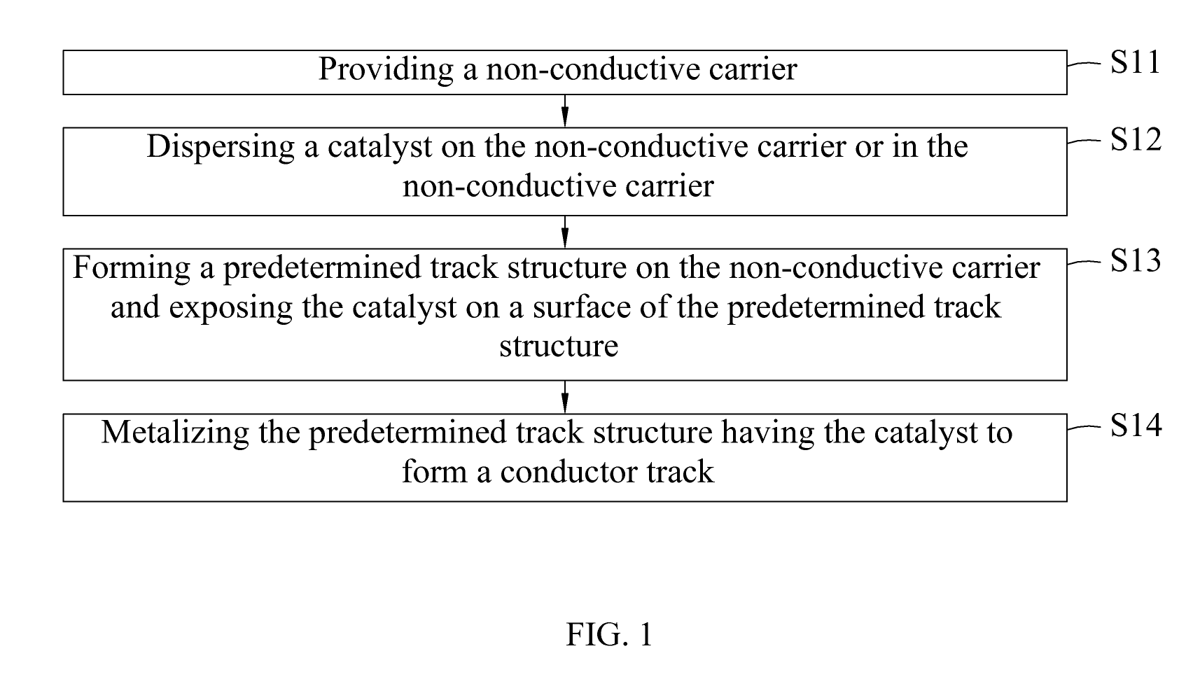

With reference to FIG. 1 for a flowchart of a manufacturing method for forming circuit structure on non-conductive carrier in accordance with a first embodiment of the invention is depicted. The method comprises the following steps: step S11, providing a non-conductive carrier; step S12, dispersing a catalyst on the non-conductive carrier or in the non-conductive carrier; step S13, forming a predetermined track structure on the non-conductive carrier and expose the catalyst on a surface of the predetermined track structure; step S14, metalizing the predetermined track structure having the catalyst to form a conductor track (metal layer). Step S11 and step S12 are simultaneously performed while dispersing the catalyst in the non-conductive carrier.

In the manufacturing method for forming circuit structure on non-conductive carrier of the invention, the catalyst can comprises metal elements or can be metal oxide, metal hydroxide, metal hydrate or composite metal oxide hydrate having the metal elements.

The metal elements can comprise transition metals or the mixture thereof such as titanium, antimony, silver, palladium, ferric, nickel, copper, vanadium, cobalt, zinc, platinum, iridium, osmium, rhodium, rhenium, ruthenium and tin. The metal oxide can include silver oxide or palladium oxide, etc. The metal hydroxide can include silver hydroxide, copper hydroxide, palladium hydroxide, nickel hydroxide, gold hydroxide, platinum hydroxide, indium hydroxide, rhenium hydroxide or rhodium hydroxide. The metal hydrate can include platinum oxide hydrate, silver oxide hydrate, copper oxide hydrate, palladium oxide hydrate, nickel oxide hydrate, gold oxide hydrate, indium oxide hydrate, rhenium oxide hydrate or rhodium oxide hydrate, etc. The composite metal oxide hydrate can be the following molecular formula:

M¹ₓM²Oₘ.n(H₂O)

M¹ is palladium or silver, and M² is silicon, titanium or zirconium. When M¹ is palladium, x is 1. When M¹ is silver, x is 2. m and n are integers between 1 to 20. The composite metal oxide hydrate can be PdTiO₃.n(H₂O), Ag₂TiO₃.n(H₂O), PdSiO₃.n(H₂O), PdZrO₃.n(H₂O) and the like.

With respect to the predetermined track structure formed on the non-conductive carrier, the forgoing carrier can be achieved by partial or overall sandblasting, laser irradiating or chemical etching to make the catalyst exposed on the predetermined track structure.

The laser manner comprises CO₂ laser, Nd: YAG (neodymium-doped yttrium aluminum garnet) laser, Nd: YVO₄ laser (neodymium-doped yttrium orthvanadate), EXCIMER laser or fiber laser. The wavelength range of laser is any wavelength between 248 nm and 10600 nm. The wavelength range of laser is determined according to whether the predetermined track structure is formed on the thin film or the non-conductive carrier, and the laser exposure time is regulated according to the laser intensity.

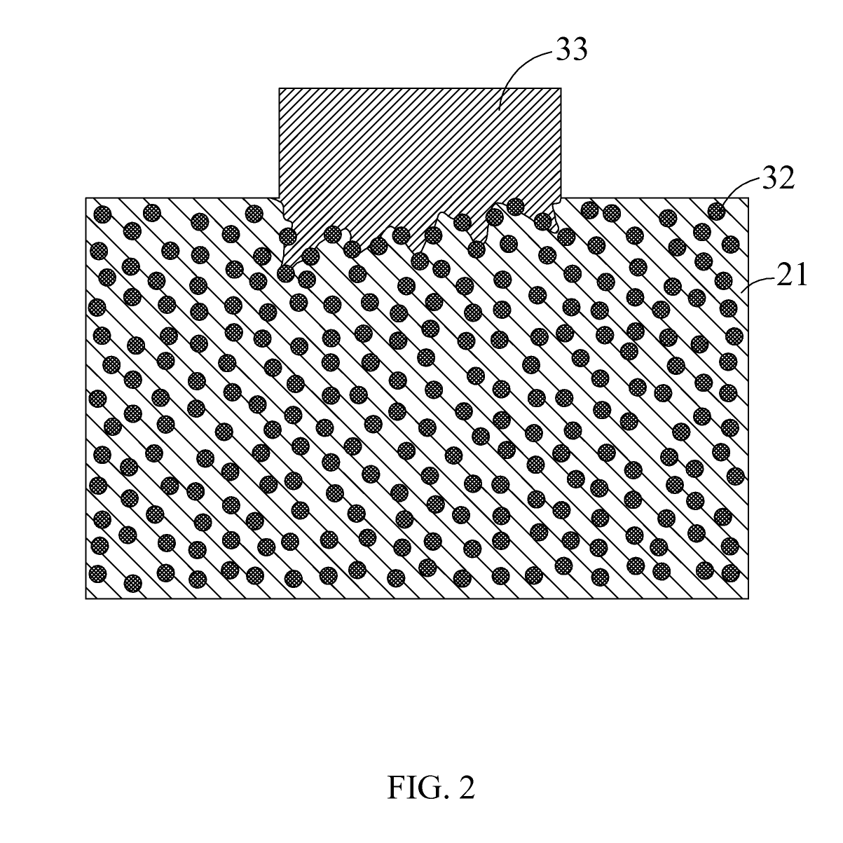

When the catalyst is directly disperse in the non-conductive carrier 21, the predetermined track structure can be directly formed on the non-conductive carrier 21 such that the catalyst 32 can be exposed on the surface of the predetermined track structure to perform metallization, thereby forming the metal layer 33 on the predetermined track structure as shown in FIG. 2.

In another embodiment, when the catalyst is dispersed on the non-conductive carrier, the thin film containing the catalyst can be utilized, for example the palladium catalyst. In step S13, the non-conductive carrier is immersed in the electroless plating solution after being processed with laser ablation, sandblasting or chemical etching. The palladium catalyst exposed to the predetermined track structure catalyzes the metal ions within the electroless solution, and the ions are reductased and precipitated on the surface of the predetermined track structure through chemical reduction reaction to further form a metal coating layer, thereby achieving a goal of producing the structural circuit on the non-conductive carrier.

With respect to different non-conductive carriers, the laser intensity of performing laser ablation is also different, and the laser exposure time is changed in accordance with laser power. For example, while taking polymer plastic material (e.g. a thermoplastic or thermosetting plastic material) as a material of a non-conductive carrier and using laser with stronger power, laser exposure time is relatively reduced to prevent the structure of the non-conductive carrier composed of the polymer plastic material from being damaged. While performing laser ablation on the non-conductive carrier composed of the thermoplastic or thermosetting plastic material, the surface of the non-conductive carrier may be decomposed and deteriorated by being overheated. However, decomposed and deteriorated byproducts may influence the effect of the catalyst. Alternatively, the catalyst amount of the catalyst thin film on the non-conductive carrier is reduced due to over-ablation such that other metals to be plated are unable to be plated in the subsequent process or not completely plated, resulting in influencing the quality of the final products.

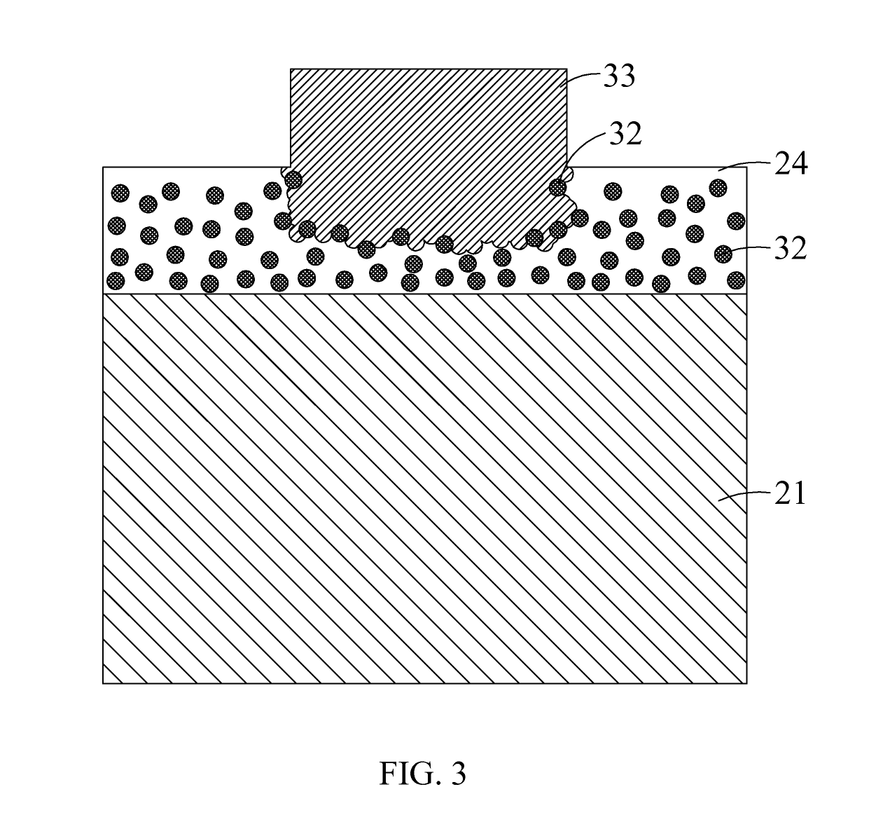

Therefore, when the non-conductive carrier 21 is composed of the polymer plastic material, the catalyst can also be formed on the non-conductive carrier 21 by the way of the thin film 24. In another word, the thin film 24 containing the catalyst is disposed on the non-conductive carrier 21, such that laser ablation can be performed on the thin film 24 without damaging the non-conductive carrier 21 composed of the polymer plastic material may not be damaged, as shown in FIG. 3. The thin film 24 can be ink, plastic films, paints or organic polymers. In addition, after plating the metals (the conductive lines are formed), the residual thin film can be selectively removed.

The thermoplastic material can include PE (polythene), PP (polypropylene), PS (polystyrene), PMMA (polymethyl methacrylate). PVC (polyvinylchloride), nylon, PC (polycarbonate), PU (polyurethane), PTFE (polytetrafluoroethylene), PET or PETE (polyethylene terephthalate), ABS (acrylonitrile butadiene styrene) or PC (polycarbonate)/ABS and a combination thereof. The thermosetting plastic material can be epoxy resin, phenol plastic material, aldehydes plastic material, polyimide, melamine-formaldehyde resin or a combination thereof. The non-conductive carrier can also be a liquid crystal polymer (LCP) material.

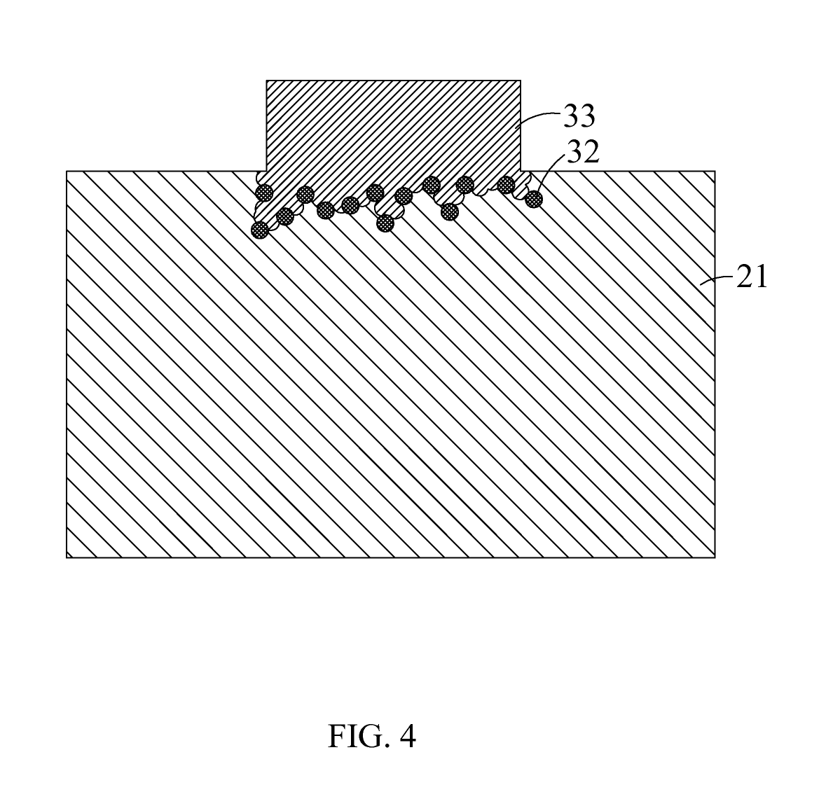

Moreover, the non-conductive carrier can be made of a ceramic material or add a glassy material in the thin film containing the catalyst on the surface of the ceramic material in order to increase the adhesive strength between the ceramic material and the catalyst after completing the sintering procedure. However, since the glassy material, which has been molten, would fill with pores on the surface of the ceramic material, laser may not easily allow the catalyst to penetrate into the non-conductive carrier made of the ceramic material. When the predetermined track structure is formed on the non-conductive carrier 21, the catalyst can be exposed on the surface of the predetermined track structure, as shown in FIG. 4. During the laser ablation, the catalyst 32 can penetrate through to and be exposed (or individually exposed) on the surface of the predetermined track structure to perform the subsequent process. The ceramic material can be aluminum oxide, aluminum nitride, low temperature co-fired ceramics (LTCC), silicon carbide, zirconium oxide, silicon nitride, boron nitride, magnesium oxide, beryllium oxide, titanium carbide, boron carbide or a combination thereof.

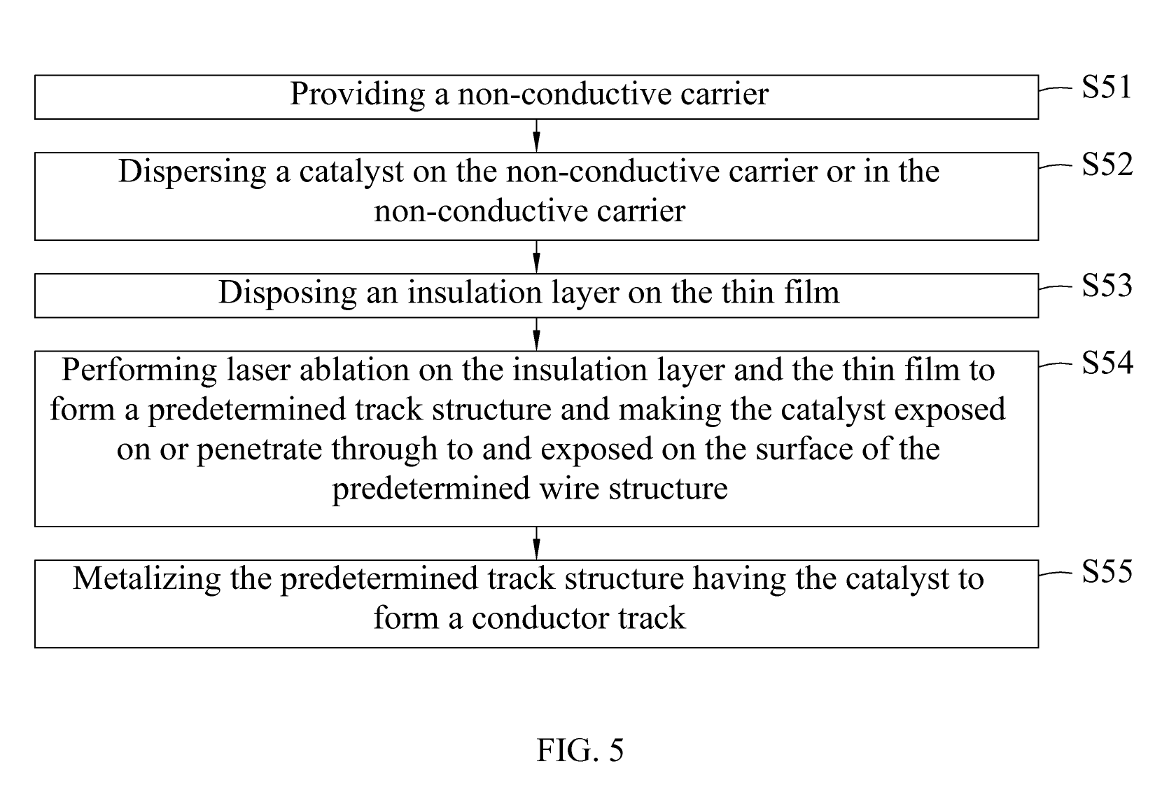

With reference to FIG. 5 for a flowchart of a manufacturing method for forming circuit structure on a non-conductive carrier in accordance with a second embodiment of the invention is depicted. The method comprises the following steps: step S51, providing a non-conductive carrier; step S52, disposing a thin film containing a catalyst on the non-conductive carrier; step S53, disposing an insulation layer on the thin film; step S54, performing laser ablation on the insulation layer and the thin film to form a predetermined track structure and make the catalyst expose on or penetrate through to and exposed on the surface of the predetermined track structure; step S55, metalizing the predetermined track structure having the catalyst to form a conductor track. In step S54, the manner of forming the predetermined track structure has many types. The embodiment takes laser ablation as an example instead of a limitation. In addition, in step S52, when the catalyst is in the non-conductive carrier, the insulation layer depicted in step S53 is directly disposed on the non-conductive carrier.

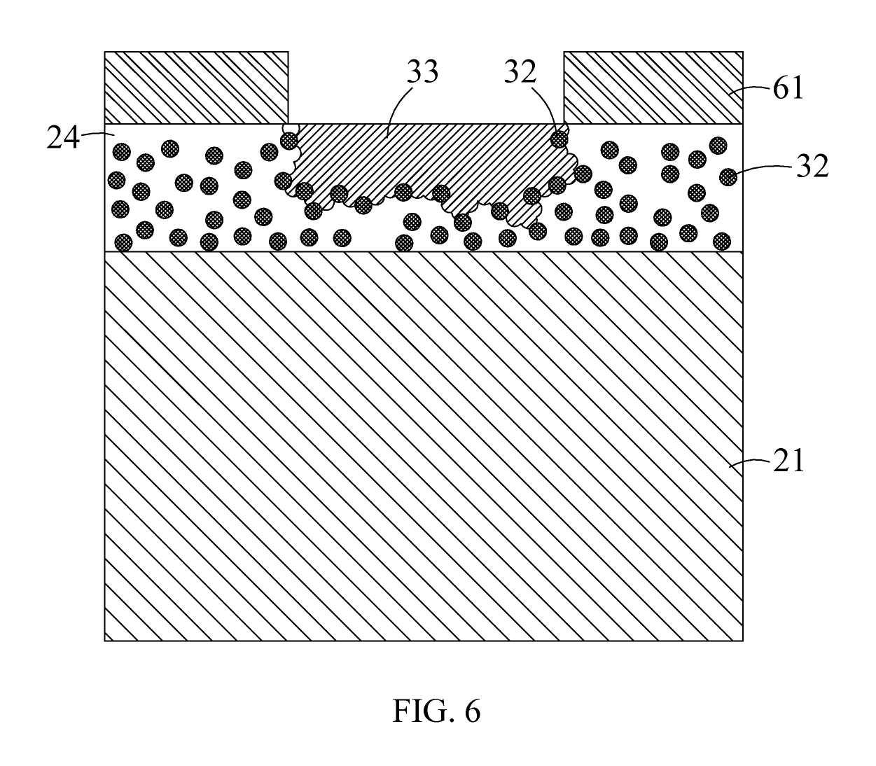

Compared with the foregoing embodiment, the second embodiment of the invention has an additional insulation layer as shown in FIG. 6. The catalyst 32 may be exposed to the portion of the surface of the thin film on the non-predetermined track structure. In the subsequent metal plating steps, the portion of the non-predetermined track structure can also be plated with metals, the undesirable influences caused by the catalyst 32 exposed to the surface of the thin film 24 can be avoided by covering the insulation layer 61 over the thin film 24.

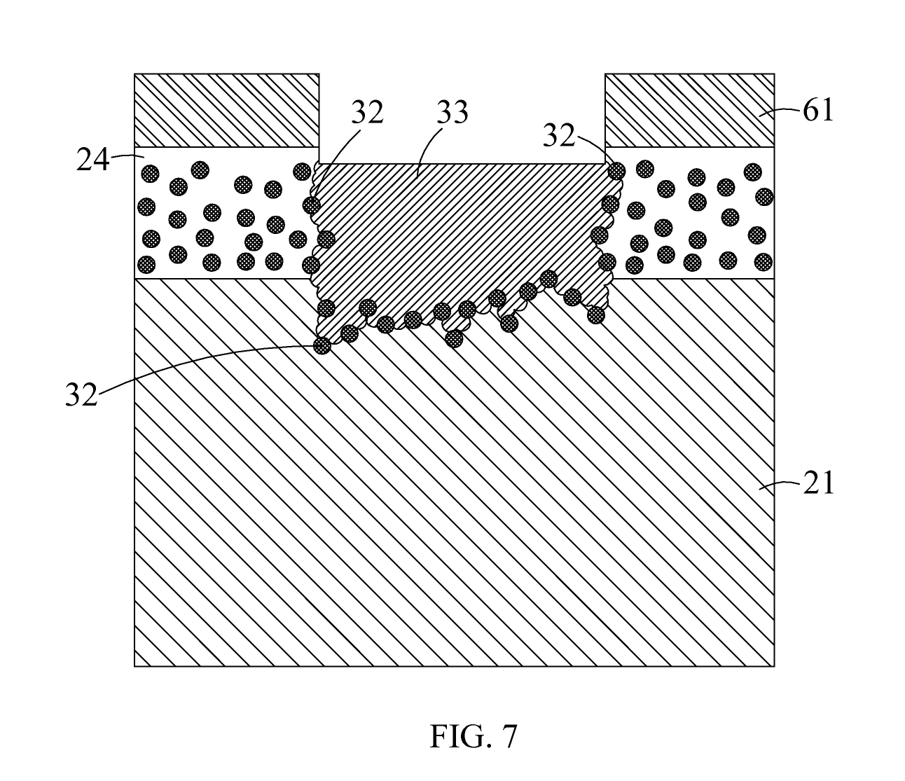

In addition, in FIG. 6, since the non-conductive carrier 21 is made of the polymer plastic material, the predetermined track structure is formed on the thin film 24 by performing laser ablation. When the non-conductive carrier 21 is made of the ceramic material, the predetermined track structure is formed on the non-conductive carrier 21 by performing laser ablation, as shown in FIG. 7. It should be noted that the circuit structure shown in FIG. 6 and FIG. 7 can be formed on the non-conductive carrier regardless of the material thereof (plastic or ceramic).

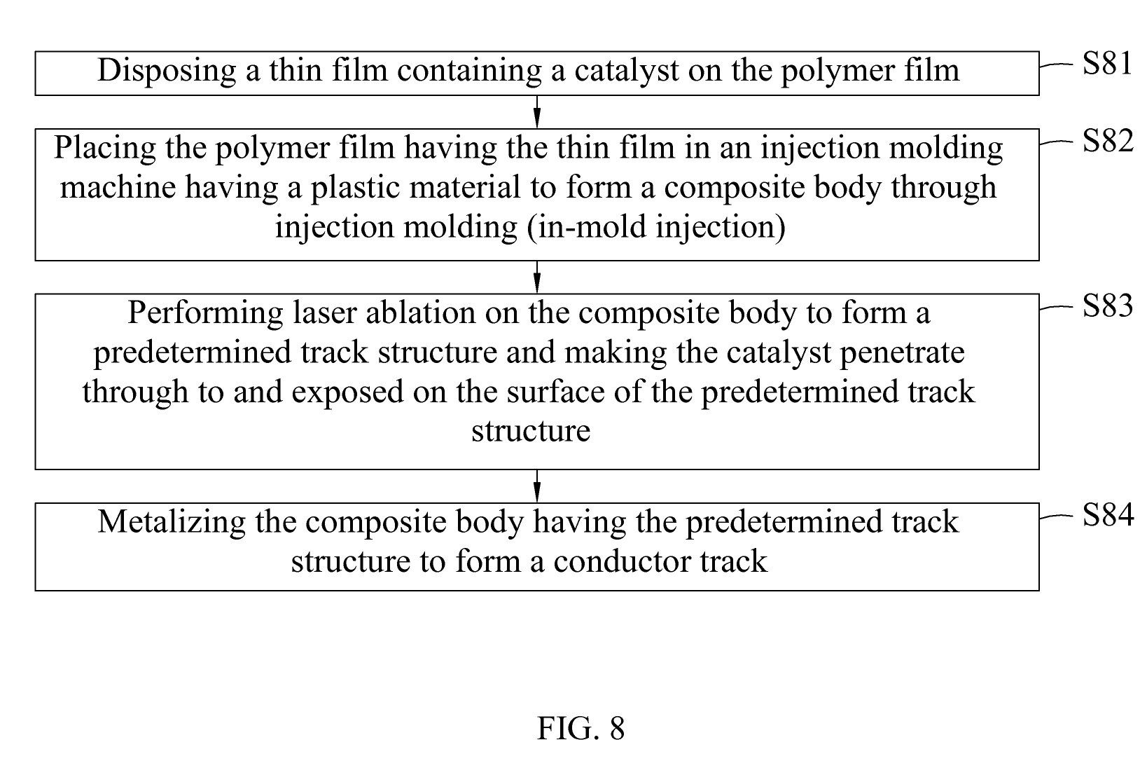

With reference to FIG. 8 for a flowchart of a manufacturing method for forming circuit structure on a non-conductive carrier in accordance with a third embodiment of the invention is depicted. The method comprises the following steps: step S81, disposing a thin film containing a catalyst on the polymer film; step S82, placing the polymer film having the thin film in an injection molding machine having a plastic material to form a composite body through injection molding (in-mold injection), wherein the plastic material is a material of a non-conductive carrier; step S83, forming a predetermined track structure by performing laser ablation on the composite body and making the catalyst penetrate through to and exposed on the surface of the predetermined track structure; step S84, metalizing the composite body having the predetermined track structure to form a conductor track. In step S83, the manner of forming the predetermined track structure has many types. The embodiment will take laser ablation as an example instead of a limitation. In addition, after forming the track structure, the polymer film can be removed.

The difference between the third embodiment and the first and second embodiment is that the third embodiment utilizes the injection molding to form the composite body composed of the polymer film, the thin film containing the catalyst and the non-conductive carrier. The composite body is directly taken as a base for circuit components. In addition, the thin film can contains patterns containing the predetermined track structures. Ablation is performed according to the patterns to form the predetermined track structures on the thin film or the non-conductive carrier, and make the catalyst exposed.

In the process of forming the composite body composed of the polymer film, the thin film containing the catalyst and the non-conductive carrier by injection molding, the conductor track patterns with different structures can be produced through different injection molding molds. In addition, the disposition positions of the thin film, the polymer film and the non-conductive carrier can also have many types. For example, while performing the injection molding, the polymer film can be disposed between the non-conductive carrier and the thin film. Alternatively, the thin film can be located between the non-conductive carrier and the polymer film. Moreover, according to different kinds of the non-conductive carrier, the degree of laser ablation may also be different. Its principle is the same as that of the foregoing embodiments, and there is no need to repeat herein. What the difference is, in the embodiment, that the polymer film can be disposed between the thin film and the non-conductive carrier. Thus, the predetermined track structures can be formed on the polymer film during the ablation process.

In the foregoing embodiments, the residual thin film can be further removed. With respect to the second embodiment, after forming the conductor track, the residual thin film can be removed in order to be dissolved to extract catalyst therefrom and reuse the catalyst. Thus, raw material cost can be cut down.

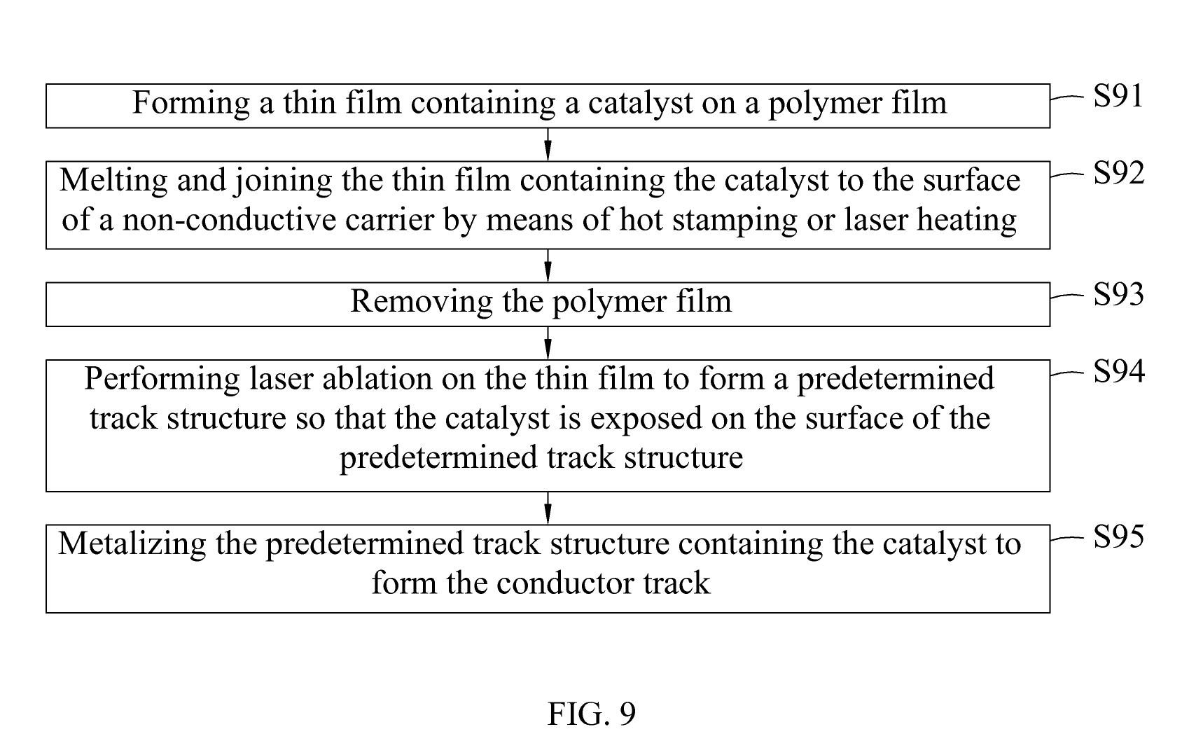

With reference to FIG. 9 for a flowchart of a manufacturing method for forming circuit structure on a non-conductive carrier in accordance with a fourth embodiment of the invention is depicted. The method comprises the following steps: step S91, forming a thin film containing a catalyst on a polymer film; step S92, melting and joining the thin film containing the catalyst to the surface of a non-conductive carrier by means of hot stamping or laser heating (including direct or indirect heating); step S93, removing the polymer film; step S94, performing laser ablation on the thin film to form a predetermined track structure so that the catalyst is exposed on the surface of the predetermined track structure; step S95, metalizing the predetermined track structure containing the catalyst to form the conductor track. According to types of the non-conductive carrier, the degree of laser ablation is different. Its principle is the same as that of the foregoing embodiments, and there is no need to describe. In step S94, the manner of forming the predetermined track structure has many types. The embodiment takes laser ablation as an example instead of a limitation.

Moreover, the catalysts depicted in the second embodiment to the fourth embodiment are similar to the first embodiment, and there is no need to depict. In addition, the foregoing catalysts take the thin film as an example instead of a limitation. Alternatively, the catalysts can be directly disposed in the non-conductive carrier. The foregoing catalysts can covered over the surface of inorganic filler. After forming composite particles, the particles are mixed into the thin film to increase specific surface area thereof. Accordingly, the catalyst number that is exposed is increased after performing laser ablation. The usage quantity of the catalysts and cost can be further reduced. The inorganic filler can contain silicic acid, silicic acid derivate, carbonic acid, carbonic acid derivate, phosphoric acid, phosphoric acid derivate, active carbon, porous carbon, carbon nanotube, graphite, zeolite, clay mineral, ceramic powder, chitin or a combination.

In the foregoing embodiments, when the non-conductive carrier is composed of a material (e.g. a polymer plastic material) with low heat conductivity, the manufacturing method of the invention can further comprise disposing a heat conduction material, a heat column or a combination thereof in the non-conductive carrier to increase the heat conduction efficiency. The heat conduction material can comprise a non-metal heat conduction material or a metal heat conduction material. The non-metal heat conduction material can be selected from a group consisting of graphite, graphene, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride and silicon carbide. The metal heat conduction material can be selected from a group consisting of lead, aluminum, gold, copper, tungsten, magnesium, molybdenum, zinc and silver. The material of the heat column can be selected from a group consisting of lead, aluminum, gold, copper, tungsten, magnesium, molybdenum, zinc, silver, graphite, grapheme, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride and silicon carbide.

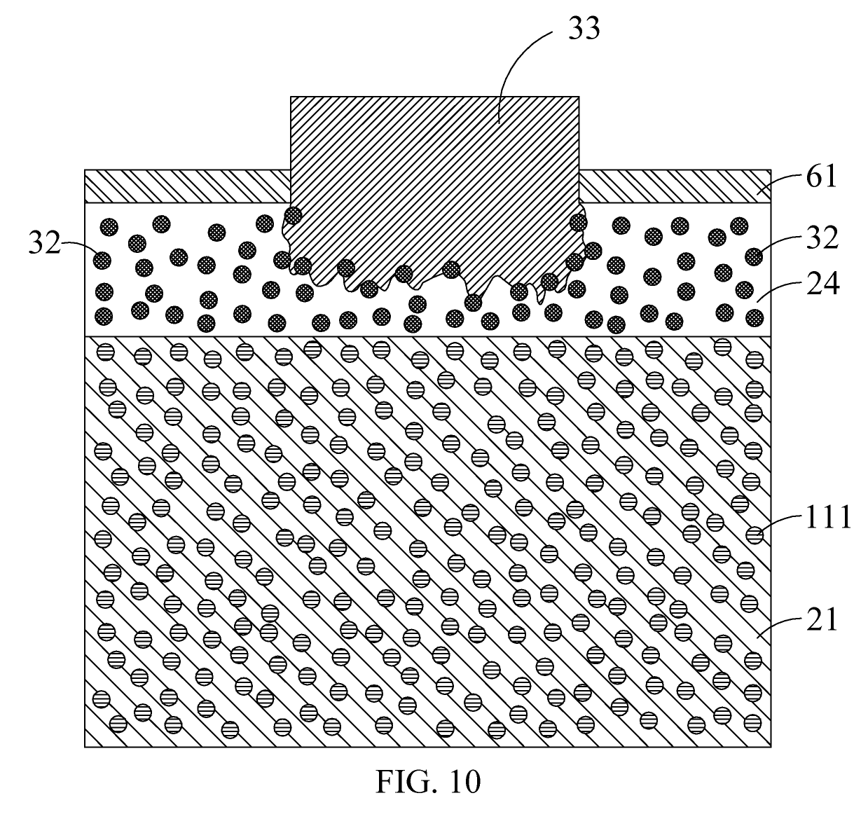

With reference to FIG. 10 for a cross-sectional drawing of a circuit containing a heat conduction material in accordance with an embodiment of the invention is depicted. The heat conduction material is carbon nanocapsules 111, a non-metal heat conduction material (which is an example instead of a limitation). The catalyst 32 exists on the thin film 24 (which is an example instead of a limitation) and can also be directly disposed in the non-conductive carrier 21 (not shown in the figure). Therefore, the obtained circuit board has excellent efficiencies of heat conduction and radiation.

To sum up, since an insulation film is disposed on the thin film containing the catalyst, and undesirable influence caused by the catalyst exposed on the non-predetermined track structure of the surface of the thin film can be avoid during the subsequent metallization process. In addition, the non-conductive carrier can include the heat conduction material, the heat column or the combination thereof so as to increase the heat conduction efficiency.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A manufacturing method for forming circuit structure on a non-conductive carrier comprising steps:
providing a non-conductive carrier;
dispersing a catalyst on the non-conductive carrier or in the non-conductive carrier;
forming a predetermined track structure on the non-conductive carrier and exposing the catalyst to the surface of the predetermined track structure; and
metalizing the predetermined track structure to form a conductor track.

2. The manufacturing method for forming circuit structure on a non-conductive carrier as recited in claim 1, wherein a sandblasting, a laser irradiating or a chemical etching is utilized so that the predetermined track structure is formed on the non-conductive carrier to expose the catalyst on the predetermined track structure.

3. The manufacturing method for forming circuit structure on a non-conductive carrier as recited in claim 2, wherein the wavelength range of the laser is any wavelength between 248 nm and 10600 nm.

4. The manufacturing method for forming circuit structure on a non-conductive carrier as recited in claim 1, further comprising a step of disposing an insulation layer on the non-conductive carrier containing the catalyst to form a composite body.

5. The manufacturing method for forming circuit structure on a non-conductive carrier as recited in claim 1, wherein a step of dispersing the catalyst on the non-conductive carrier is achieved by disposing a thin film containing the catalyst on the surface of the non-conductive carrier.

6. The manufacturing method for forming circuit structure on a non-conductive carrier as recited in claim 5, further comprising a step of removing a residual thin film after forming the conductor track.

7. The manufacturing method for forming circuit structure on a non-conductive carrier as recited in claim 5, wherein the thin film comprises an ink, paint, organic polymer or a combination thereof.

8. The manufacturing method for forming circuit structure on a non-conductive carrier as recited in claim 1, further comprising a step of covering the catalyst on a surface of an inorganic filler to increase a specific surface area of the catalyst, wherein the inorganic filler comprises silicic acid, silicic acid derivate, carbonic acid, carbonic acid derivate, phosphoric acid, phosphoric acid derivate, active carbon, porous carbon, carbon nanotube, graphite, zeolite, clay mineral, ceramic powder, chitin or a combination thereof.

9. The manufacturing method for forming circuit structure on a non-conductive carrier as recited in claim 1, wherein the catalyst comprises a metal element, or a metal oxide of the metal element, a metal hydroxide of the metal element, metal hydrate of the metal element, a composite metal oxide hydrate of the metal element or a combination thereof associated with the metal element.

10. The manufacturing method for forming circuit structure on a non-conductive carrier as recited in claim 9, wherein the metal element comprises titanium, antimony, silver, palladium, ferric, nickel, copper, vanadium, cobalt, zinc, platinum, gold, indium, iridium, osmium, rhodium, rhenium, ruthenium, tin and a combination thereof.

11. The manufacturing method for forming circuit structure on a non-conductive carrier as recited in claim 9, wherein the metal oxide comprises silver oxide, palladium oxide or a combination thereof.

12. The manufacturing method for forming circuit structure on a non-conductive carrier as recited in claim 9, wherein the metal hydroxide comprises silver hydroxide, copper hydroxide, palladium hydroxide, nickel hydroxide, gold hydroxide, platinum hydroxide, indium hydroxide, rhenium hydroxide, rhodium hydroxide or a combination thereof.

13. The manufacturing method for forming circuit structure on a non-conductive carrier as recited in claim 9, wherein the metal hydrate comprises platinum oxide hydrate, silver oxide hydrate, copper oxide hydrate, palladium oxide hydrate, nickel oxide hydrate, gold oxide hydrate, indium oxide hydrate, rhenium oxide hydrate, rhodium oxide hydrate or a combination thereof.

14. The manufacturing method for forming circuit structure on a non-conductive carrier as recited in claim 9, wherein the composite metal oxide hydrate comprises a molecular formula:
M¹ₓM²Oₘ.n(H₂O), and M¹ is palladium or silver, and M² is silicon, titanium or zirconium, and when M¹ is palladium, x is 1, and when M¹ is silver, x is 2. m and n are integers between 1 to 20.

15. The manufacturing method for forming circuit structure on a non-conductive carrier as recited in claim 1, wherein a material of the non-conductive carrier is a polymer plastic material, and the polymer plastic material is a thermoplastic material or a thermosetting plastic material.

16. The manufacturing method for forming circuit structure on a non-conductive carrier as recited in claim 1, wherein a material of the non-conductive carrier is a ceramic material, and the ceramic material comprises aluminum oxide, aluminum nitride, low temperature co-fired ceramics (LTCC), silicon carbide, zirconium oxide, silicon nitride, boron nitride, magnesium oxide, beryllium oxide, titanium carbide, boron carbide or a combination thereof.

17. The manufacturing method for forming circuit structure on a non-conductive carrier as recited in claim 1, further disposing a heat conduction material, a heat column or a combination thereof in the non-conductive carrier.

18. The manufacturing method for forming circuit structure on a non-conductive carrier as recited in claim 17, wherein the heat conduction material comprises a non-metal heat conduction material, a metal heat conduction material or a combination thereof.

19. The manufacturing method for forming circuit structure on a non-conductive carrier as recited in claim 18, wherein the non-metal heat conduction material is selected from a group consisting of graphite, graphene, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride and silicon carbide or a combination thereof.

20. The manufacturing method for forming circuit structure on a non-conductive carrier as recited in claim 18, wherein the metal heat conduction material is selected from a group consisting of lead, aluminum, gold, copper, tungsten, magnesium, molybdenum, zinc, silver or a combination thereof.

21. The manufacturing method for forming circuit structure on a non-conductive carrier as recited in claim 17, wherein a material of the heat column is selected from a group consisting of lead, aluminum, gold, copper, tungsten, magnesium, molybdenum, zinc, silver, graphite, grapheme, diamond, carbon nanotube, carbon nanocapsule, nanobubble, carbon sixty, nanocone, nanohorn, carbon nanopipet, microtree, beryllium oxide, aluminum oxide, boron nitride, aluminum nitride, magnesium oxide, silicon nitride, silicon carbide or a combination.
